(19) United States
(12) Patent Application Publication
(10) Pub. No.: US 2023/0376656 A1
(43) Pub. Date: Nov. 23, 2023

(54) Efficient Neural Style Transfer For Fluid Simulations

(71) Applicant: Disney Enterprises, Inc., Burbank, CA (US)

(72) Inventors: Vinicius Da Costa De Azevedo, Zurich (CH); Silvia Nauer, Castel San Pietro (CH); Joshua Aurand, Zurich (CH); Raphael François Ortiz, Dübendorf (CH)

(21) Appl. No.: 18/137,270

(22) Filed: Apr. 20, 2023

Related U.S. Application Data
(60) Provisional application No. 63/343,891, filed on May 19, 2022.

(51) Int. Cl. G06F 30/28

(52) U.S. Cl. CPC G06F 30/28

(57) ABSTRACT

A system includes a hardware processor, and a system memory storing a software code and a machine learning (ML) model trained to apply a stylization to an image. The hardware processor executes the software code to receive a first sequence of images and style data describing a desired stylization of content depicted by the first sequence of images. The hardware processor further executes the software code to stylize the content, using the ML model, to provide a stylized content having the desired stylization, wherein stylizing includes applying an exponential moving average (EMA) temporal smoothing algorithm to sequential image pairs of the first sequence of images to generate a second sequence of images providing a depiction of the content having the desired stylization, and output the stylized content having the desired stylization.

### RELATED APPLICATIONS

The present application claims the benefit of and priority to a pending U.S. Provisional Patent Application Ser. No. 63/343,891 filed on May 19, 2022, and titled “Efficient Neural Style Transfer for Fluid Simulations,” which is hereby incorporated fully by reference into the present application.

### BACKGROUND

Artistically controlling fluids is a challenging task. One approach to addressing this challenge is to use volumetric neural style transfer techniques to manipulate fluid simulation data. However, applying volumetric style transfer algorithms directly to production in their original formulation is impracticable, and several changes are needed to adapt the approach to production pipelines. Moreover, the energy minimization solved by conventional methods is camera dependent (hereinafter “view-dependent”). To avoid that view dependency, a computationally expensive iterative optimization must typically be performed for multiple views sampled around the original simulation, which can undesirably take up to several minutes per frame. Thus, there is a need in the art for a fluid simulation solution enabling stylizations that are significantly faster, simpler, more controllable, and less prone to artifacts than conventional approaches.

### BRIEF DESCRIPTION OF THE DRAWINGS

FIG. 1A shows an exemplary system for performing efficient neural style transfer (efficient NST) for fluid simulations, according to one implementation;

FIG. 1B contrasts view-dependent and view-independent stylized content, according to one implementation;

FIG. 2 shows a flowchart presenting an exemplary method for performing efficient NST for fluid simulations, according to one implementation;

FIG. 3 shows the effects of different exemplary temporal smoothing weights on stylizations produced using an exponential moving average (EMA) algorithm, according to various implementations;

FIG. 4 presents exemplary pseudocode of an algorithm for coupling EMA smoothing with velocity-based stylization, according to one implementation; and

FIG. 5 shows a diagram of an exemplary feed-forward convolutional neural network architecture suitable for use in providing view-independent stylized content.

### DETAILED DESCRIPTION

The following description contains specific information pertaining to implementations in the present disclosure. One skilled in the art will recognize that the present disclosure may be implemented in a manner different from that specifically discussed herein. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

The present application discloses systems and methods for performing efficient neural style transfer (NST) for fluid simulations. As stated above, artistically controlling fluids is a challenging task. One approach to addressing this challenge is to use conventional volumetric NST techniques to manipulate fluid simulation data. However, applying volumetric style transfer algorithms directly to production in their original formulation is impracticable, and several changes are needed to adapt the approach to production pipelines. Moreover, the energy minimization solved by conventional methods is view-dependent. To avoid that view dependency, a computationally expensive iterative optimization must typically be performed for multiple views sampled around the original simulation, which can undesirably take up to several minutes per frame.

The novel and inventive approach disclosed by the present application adapts volumetric style transfer methods (transport-based and particle-based) to production pipelines by making them more efficient and customizable while also reducing artifacts created by previous techniques. Moreover, the present disclosure provides a simple architecture that is able to ensure that stylizations are consistent for arbitrary views, removing the view dependency of the screen-space style transfer. It is noted that the style transfer loss (Gram Matrix) is computed at the image (screen)-space. By contrast, the style space is an abstraction that can represent all possible stylizations of a certain image.

It is further noted that the present solution for performing efficient NST for fluid simulations can advantageously be implemented as automated systems and methods. As defined in the present application, the terms “automation,” “automated,” and “automating” refer to systems and processes that do not require the participation of a human system operator. Thus, the methods described in the present application may be performed under the control of hardware processing components of the disclosed automated systems.

It is also noted that the present approach implements trained machine learning (ML) models, which, once trained, are very efficient, and can provide stylizations that are two orders of magnitude faster than can be achieved using a conventional optimization-based pipeline. Moreover, the complexity involved in providing the stylizations disclosed in the present application requires such trained models because human performance of the present solution in feasible timeframes is impossible, even with the assistance of the processing and memory resources of a general purpose computer.

As defined in the present application, the expression “machine learning model” or “ML model” may refer to a mathematical model for making future predictions based on patterns learned from samples of data or “training data.” For example, machine learning models may be trained to perform image processing, natural language understanding (NLU), and other inferential data processing tasks. Various learning algorithms can be used to map correlations between input data and output data. Such a ML model may include one or more logistic regression models, Bayesian models, or artificial neural networks (NNs). A “deep neural network,” in the context of deep learning, may refer to a NN that utilizes multiple hidden layers between input and output layers, which may allow for learning based on features not explicitly defined in raw data.

Examples of the types of content to which the present solution for performing efficient NST for fluid simulations may be applied include simulations of volumetric objects, as well as fluid phenomena in general, such as smoke for example. That content may be depicted by a sequence of images, such as video. Moreover, that content may be depicted as one or more simulations present in a real-world, virtual reality (VR), augmented reality (AR), or mixed reality (MR) environment. Moreover, that content may be depicted as present in virtual worlds that can be experienced by any number of users synchronously and persistently, while providing continuity of data such as personal identity, user history, entitlements, possessions, payments, and the like. It is noted that the solution for performing efficient NST for fluid simulations disclosed by the present application may also be applied to content that is depicted by a hybrid of traditional audio-video and fully immersive VR/AR/MR experiences, such as interactive video.

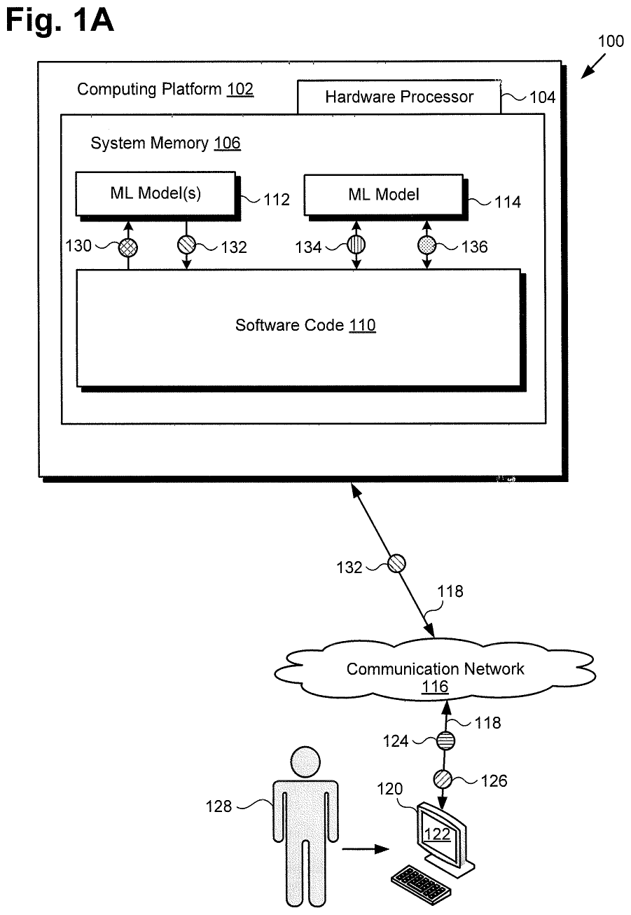

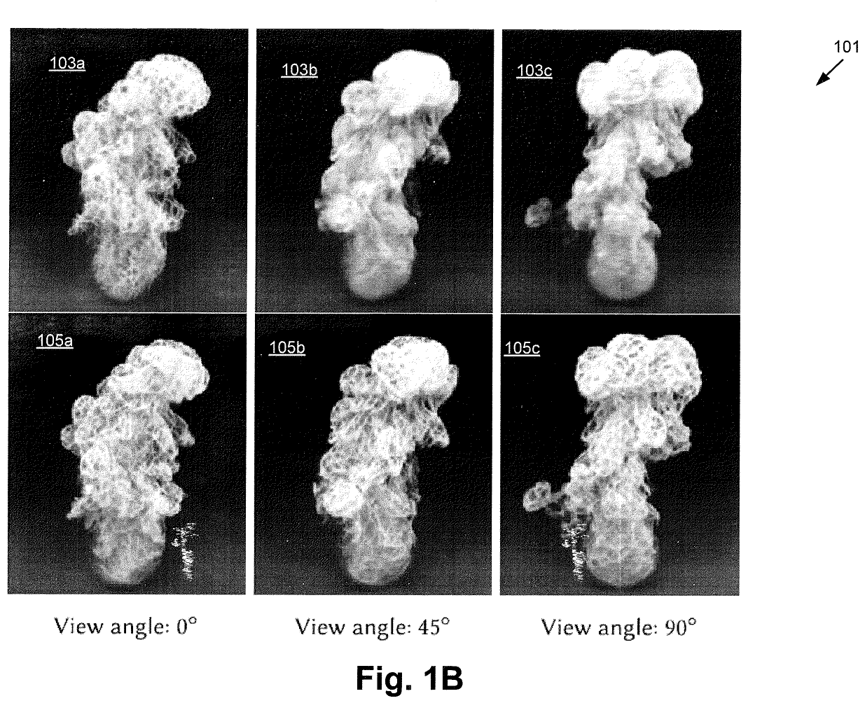

FIG. 1A shows exemplary system 100 for performing efficient NST for fluid simulations, according to one implementation. As shown in FIG. 1A, system 100 includes computing platform 102 having hardware processor 104 and system memory 106 implemented as a computer-readable non-transitory storage medium. According to the present exemplary implementation, system memory 106 stores software code 110, one or more ML models 112 trained to stylize content (hereinafter “ML model(s) 112”), and optional ML model 114 trained to transform stylized content to view-independent stylized content. In some examples, ML model(s) 112 may be NNs.

Referring to FIG. 1B, diagram 101 in FIG. 1B contrasts view-dependent and view-independent stylized content, according to one implementation. It is noted that the style transfer pipeline disclosed by the present application takes a camera as an input, and the stylization is computed on the final rendered image (screen space). As a result, a view-dependent stylization does not produce stylized results from viewing angles other than that of the input camera. This is shown by images 103a, 103b, and 103c of view-dependent stylized content from respective view angles 0°, 45°, and 90°, where view angle 0° is the perspective of the input camera. As may be seen from FIG. 1B, only image 103a viewed from the input camera perspective includes stylizations, while images 103b and 103c from other perspectives show non-stylized content. By contrast, images 105a, 105b, and 105c of view-independent stylized content show the stylizations from all perspectives.

Referring once again to FIG. 1A, as further shown in FIG. 1A, system 100 is implemented within a use environment including communication network 116, client system 120 including display 122, and user 128 of system 100 and client system 120, who may be an artist for example. In addition, FIG. 1A shows first sequence of images 124, style data 126 describing a desired stylization of content 130 depicted by first sequence of images 124, and stylized content 132 providing a depiction of that content having the desired stylization. That is to say, content 130 depicted by first sequence of images 124 is stylized according to style data 126 by system 100, and that content including the desired stylization is output by system 100 to client system 120 as stylized content 132. Also shown in FIG. 1A are view-dependent second sequence of images 134 (i.e., the sequence of images matches the style for a set of specified cameras) included in stylized content 132 output by ML model(s) 112, view-independent sequence of images 136, and network communication links 118 of communication network 116 interactively connecting system 100 and client system 120.

Although the present application refers to software code 110, ML model(s) 112, and ML model 114 as being stored in system memory 106 for conceptual clarity, more generally, system memory 106 may take the form of any computer-readable non-transitory storage medium. The expression “computer-readable non-transitory storage medium,” as used in the present application, refers to any medium, excluding a carrier wave or other transitory signal that provides instructions to hardware processor 104 of computing platform 102. Thus, a computer-readable non-transitory storage medium may correspond to various types of media, such as volatile media and non-volatile media, for example. Volatile media may include dynamic memory, such as dynamic random access memory (dynamic RAM), while non-volatile memory may include optical, magnetic, or electrostatic storage devices. Common forms of computer-readable non-transitory storage media include, for example, optical discs such as DVDs, RAM, programmable read-only memory (PROM), erasable PROM (EPROM), and FLASH memory.

Moreover, although FIG. 1A depicts software code 110, ML model(s) 112, and ML model 114 as being co-located in system memory 106, that representation is also provided merely as an aid to conceptual clarity. More generally, system 100 may include one or more computing platforms 102, such as computer servers for example, which may be co-located, or may form an interactively linked but distributed system, such as a cloud-based system or blockchain, for instance. As a result, hardware processor 104 and system memory 106 may correspond to distributed processor and memory resources within system 100. Consequently, in some implementations, one or more of software code 110, ML model(s) 112, and ML model 114 may be stored remotely from one another on the distributed memory resources of system 100. It is also noted that, in some implementations, some or all of ML model(s) 112 and ML model 114 may take the form of software modules included in software code 110.

Hardware processor 104 may include multiple hardware processing units, such as one or more central processing units, one or more graphics processing units, and one or more tensor processing units, one or more field-programmable gate arrays (FPGAs), custom hardware for machine-learning training or inferencing, and an application programming interface (API) server, for example. By way of definition, as used in the present application, the terms “central processing unit” (CPU), “graphics processing unit” (GPU), and “tensor processing unit” (TPU) have their customary meaning in the art. That is to say, a CPU includes an Arithmetic Logic Unit (ALU) for carrying out the arithmetic and logical operations of computing platform 102, as well as a Control Unit (CU) for retrieving programs, such as software code 110, from system memory 106, while a GPU may be implemented to reduce the processing overhead of the CPU by performing computationally intensive graphics or other processing tasks. A TPU is an application-specific integrated circuit (ASIC) configured specifically for AI processes such as machine learning.

In some implementations, computing platform 102 may correspond to one or more web servers accessible over a packet-switched network such as the Internet, for example. Alternatively, computing platform 102 may correspond to one or more computer servers supporting a wide area network (WAN), a local area network (LAN), or included in another type of private or limited distribution network. In addition, or alternatively, in some implementations, system 100 may utilize a local area broadcast method, such as User Datagram Protocol (UDP) or Bluetooth, for instance. Furthermore, in some implementations, system 100 may be implemented virtually, such as in a data center. For example, in some implementations, system 100 may be implemented in software, or as virtual machines. Moreover, in some implementations, communication network 116 may be a high-speed network suitable for high performance computing (HPC), for example a 10 GigE network or an Infiniband network.

It is further noted that, although client system 120 is shown as a desktop computer in FIG. 1A, that representation is provided merely by way of example. In other implementations, client system 120 may take the form of any suitable mobile or stationary computing device or system that implement data processing capabilities sufficient to provide a user interface, support connections to communication network 116, and implement the functionality ascribed to client system 120 herein. That is to say, in other implementations, client system 120 may take the form of a laptop computer, tablet computer, or smartphone, to name a few examples. In still other implementations, client system 120 may be a peripheral device of system 100 in the form of a dumb terminal. In those implementations, client system 120 may be controlled by hardware processor 104 of computing platform 102.

It is also noted that display 122 of client system 120 may take the form of a liquid crystal display (LCD), a light-emitting diode (LED) display, an organic light-emitting diode (OLED) display, a quantum dot (QD) display, or any other suitable display screen that perform a physical transformation of signals to light. Furthermore, display 122 may be physically integrated with client system 120 or may be communicatively coupled to but physically separate from client system 120. For example, where client system 120 is implemented as a smartphone, laptop computer, or tablet computer, display 122 will typically be integrated with client system 120. By contrast, where client system 120 is implemented as a desktop computer, display 122 may take the form of a monitor separate from client system 120 in the form of a computer tower.

By way of overview, NST is a technique for artistically stylizing an image while keeping its original content. NST computes styles by filter activations of pre-trained deep convolutional NNs (CNNs) used for image classification, providing a range of styles that can model both artistic and photo-realistic style transfers. Other methods for computing volumetric neural style transfer extend image-based ones by manipulating three-dimensional (3D) fluid data through Eulerian or Lagrangian frameworks. The other methods rely on an iterative optimization which minimizes differences between filter activations of a given target style and the style of a rendered fluid frame for example. Given a specified camera viewpoint, a differentiable volumetric renderer automatically enables the transfer of gradients computed in image-space to volumetric data. Temporally coherent fluid stylizations can be obtained either by subsequently aligning and smoothing stylization velocity fields or by smoothing particle corrections over multiple frames. These volumetric style transfer algorithms enable a wide variety of styles obtained from single two-dimensional (2D) images, ranging from simple artistic patterns to intricate motifs. However, applying conventional NST, TNST, or LNST directly to production in their original formulation is ineffective. It is noted that the entire disclosure of each of the following two papers, the first describing TNST and the second describing LNST in greater detail, are hereby incorporated by reference into the present application:
Kim et al., titled “Transport-Based Neural Style Transfer for Smoke Simulations,” published in ACM Transactions on Graphics Volume 38 Issue, dated Dec. 6, 2019, Article No.: 188, pp 1-11, https://doi.org/10.1145/3355089.3356560 (hereinafter referred to as “Kim et al. [2019]”); and
Kim et al., titled “Lagrangian neural style transfer for fluids,” published in ACM Transactions on Graphics Volume 39 Issue, dated Aug. 4, 2020, Article No.: 52, pp 52:1-52:10, https://doi.org/10.1145/3386569.3392473 (hereinafter referred to as “Kim et al. [2020]”).

As noted above, the efficient NST for fluid simulation solution disclosed by the present application adapts volumetric style transfer methods (transport-based TNST and particle-based LNST) to production pipelines by making them more efficient and customizable while also reducing artifacts created by previous techniques. With respect to the distinction between the characterizations “transport-based” and “particle-based,” it is noted that the transport-based approach computes velocities on a volumetric grid that will push a fluid simulation towards stylization (hence the term “transport” in its name). The particle-based approach first pre-processes the volumetric grid to a set of particles for creating an efficient stylization pipeline. The style transfer is then performed on the quantities represented by these particles (either their position or density). The efficient NST approach disclosed by the present application advances the state-of-the-art by rendering the transport-based approach more efficient without requiring conversion of the fluid simulation to particles as is done in the particle-based approach.

As also noted above, the present disclosure provides a simple architecture that is able to ensure that stylizations are consistent for arbitrary views, removing the view dependency of the screen-space style transfer. Contributions to the state-of-the-art provided by the present efficient NST solution include, but are not limited to, a simplified and more efficient mathematical optimization formulation in which costly advection algorithms are replaced by simpler mapping functions without loss of quality, an improved temporal smoothing algorithm that improves the transport-based algorithm running time by more than two orders of magnitude, an extension of the original transport-based approach to work directly with density values through a multiplicative factor, and an efficient feed-forward architecture that is able to stylize volumetric simulations from arbitrary viewpoints, i.e., produce view-independent stylizations.

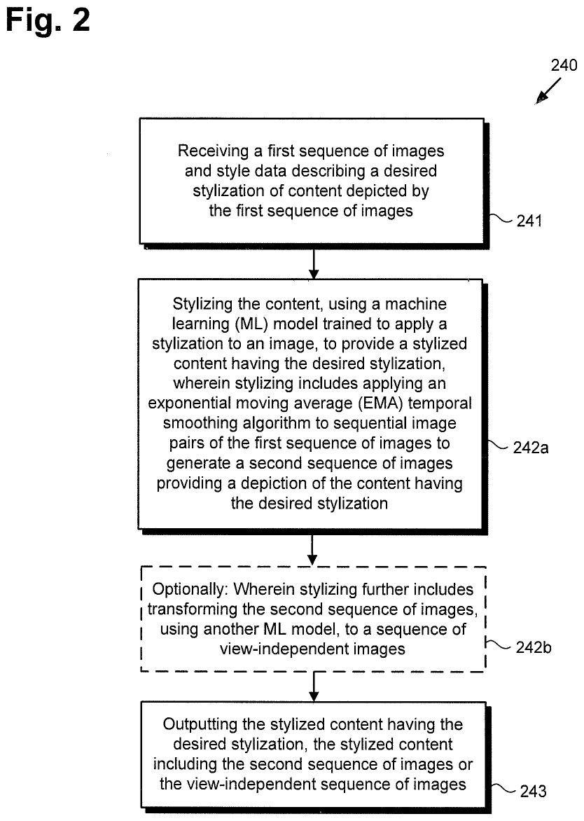

The functionality of system 100 including software code 110 will be further described by reference to FIG. 2, which shows flowchart 240 presenting a method for performing efficient NST for fluid simulations, according to one exemplary implementation. With respect to the actions described in FIG. 2, it is noted that certain details and features have been left out of flowchart 240 in order not to obscure the discussion of the inventive features in the present application. It is further noted that, in various implementations the actions 241, 242, and 243 of flowchart 240 described below may be performed in an automated process.

Referring to FIG. 2 in combination with FIG. 1A, flowchart 240 includes receiving first sequence of images 124 and style data 126 describing a desired stylization of content 130 depicted by first sequence of images 124 (action 241). First sequence of images 124 may include a plurality of 2D images, for example, depicting content 130. Content 130 may include simulations of volumetric objects, as well as simulations of fluids in motion, such as fire, liquid (e.g., water), or gas (e.g., air), for example, or a suspension of airborne particulates in motion, such as smoke. Moreover, and as alluded to above, content 130 may be depicted as one or more simulations present in a real-world, VR, AR, or MR environment, and may be depicted as present in virtual worlds that can be experienced by any number of users synchronously and persistently, while providing continuity of data such as personal identity, user history, entitlements, possessions, payments, and the like.

Style data 126 may include any of a large number of parameters. Examples of parameters that may be included in style data 126 are image size, which layers of a NN included in ML model(s) 112 will be used to produce the stylization, how many iterations will be performed, and the learning rate, to name a few. First sequence of images 124 and style data 126 describing the desired stylization of content 130 depicted by first sequence of images 124 may be received in action 241 by software code 110, executed by hardware processor 104 of system 100.

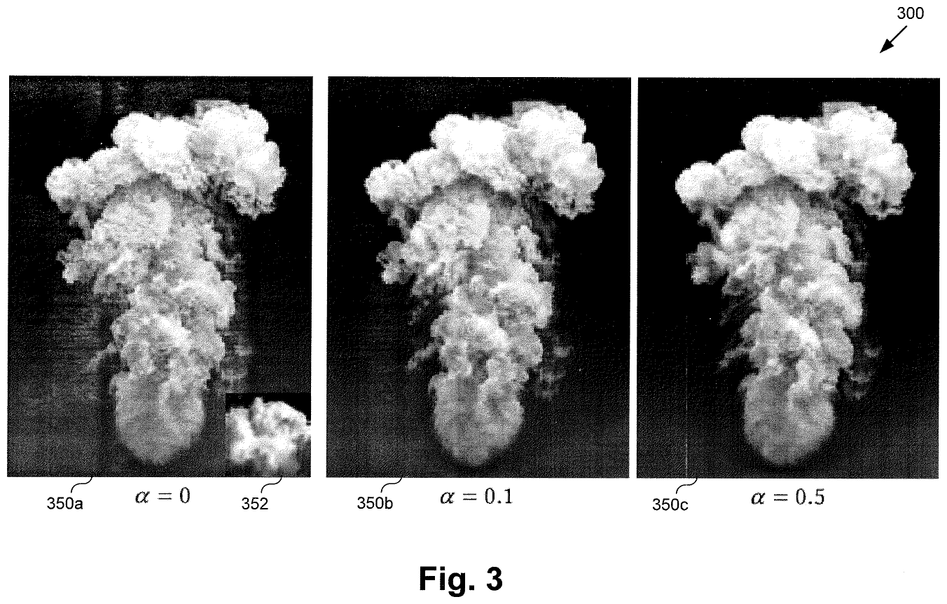

Continuing to refer to FIGS. 1A and 2 in combination, flowchart 240 further includes stylizing content 130, using ML model(s) 112, which may be implemented as a trained NN for example, to provide stylized content 132 having the desired stylization, wherein stylizing includes applying an exponential moving average (EMA) temporal smoothing algorithm to sequential image pairs of first sequence of images 124 to generate second sequence of images 134 providing a depiction of content 130 having the desired stylization (action 242a). The EMA temporal smoothing algorithm is used to average contributions from different image frames and works with contributions that are applied to the whole volume of the fluid simulation. As discussed below by reference to Equation 4, a transport operator T aligns the stylization velocities (vₜ₋₁) from a previous image frame by transporting them with the underlying simulation velocity (uₜ₋₁). Then this aligned contribution from the previous image frame is merged with the current one by a combination of a weights described below by reference to FIG. 3.

As noted above, optional ML model 114 is trained to transform stylized content to view-independent stylized content, as described below by reference to optional action 242b of flowchart 240. It is noted that in implementations in which ML model 114 is omitted from system 100, stylized content 132 may include view-dependent second sequence of images 134. However, in implementations in which optional ML model 114 is included as a feature of system 100, stylized content may include view-independent sequence of images 136. Action 242a may be performed by software code 110, executed by hardware processor 104 of system 100, and using ML model(s) 112.

By way of context, the TNST approach described in Kim et al. [2019] describes an optimization-based NST algorithm that supports volumetric smoke stylization, and is also applicable to stylization of other volumetric fluids. TNST proposes a multi-level velocity-based approach that naturally follows the input simulation, since the optimization is constrained to deform densities indirectly through transport. A velocity field D is iteratively optimized for stylizing an input density d, minimizing the loss:

\hat{v}=argmin vΣ_{θ∈Θ}L(R_{θ}(T(d,v)),p), (Equation 1)

where T is a transport function, R is a differential renderer, θ is a camera configuration from a set of camera views Θ, and p denotes user-defined parameters. To obtain volumetric 3D structures, the optimization integrates multiple camera configurations sampled within a specified range of settings, each optimizing the loss for an individual camera viewpoint. The loss function L is the style loss described by Kim et al. [2020].

TNST velocities v can be irrotational (v=∇ϕ), incompressible (v=∇×ψ) or a mixture of both. While incompressibility is desired for fluid simulations, it can be an overly restricting requirement for optimization, particularly when coupled with higher order integrators. Since the algorithm used by ML model(s) 112 to minimize the style loss function for the style transfer is mostly concerned with matching screen-space gradients that get back-propagated to 3D through the shape/transmittance function of the input smoke, advection-order and incompressibility play a secondary role in stylization quality. As a result, the present efficient NST solution can be made more efficient than TNST by simplifying the transport function to be a Semi-Lagrangian method with a first-order Euler integrator. In practice, the optimizer finds a linear velocity field to warp densities as:

T(d,v)≈I(d,g+v), (Equation 2)

where I is an interpolation function and g represents grid density locations, respectively. It is noted that the approach disclosed in the present application adopts trilinear interpolation.

TNST optimizes Equation (1) above iteratively per-frame due to memory limitations. To enforce temporal coherency, neighboring stylization velocities are first aligned by advection with the baseline simulation. After alignment, these velocities are combined by Gaussian smoothing with a compact kernel that spans w frames. While this approach was able to create temporally coherent volumetric stylizations with 2D input images, it had a crucial limitation:

$$\frac{( {w}^{2} - 1 )}{4}$$

advections are required per single-frame iteration, which made the method extremely inefficient. A Lagrangian version of the algorithm, LNST, described in Kim et al. [2020] improves this limitation by recasting the optimization of Equation (1) to a particle-based framework as:

λ°=arg min λ°Σ_{θ∈Θ}L(R_{θ}(I_{p2g}(x°,λ°),p)), (Equation 3)

where λ° are per-particle attributes (e.g., density (ρ°) or positions (x°)), and I_{p2g} is a transfer function that maps particle attributes into a grid. LNST enforces temporal coherency by Gaussian smoothing of particle attribute changes, which is simple and efficient since it requires no alignment between adjacent frames. However, LNST requires a pre-processing step for converting grid-based smoke simulations to particles. This conversion has to enforce a minimal amount of well-distributed particles through the entire simulation, which is crucial for both the efficiency of the stylization and for guaranteeing a good reconstruction quality of the original grid-based smoke. The grid-to-particle conversion is implemented through a multi-level optimization process that is time consuming and has several parameters that require careful tuning. It can be specially burdensome for productions since it does not scale well for large simulations, generating considerable amounts of data in storage-bound production environments.

According to the efficient NST approach disclosed herein, the shortcomings in LNST described above can be addressed by recognizing that contributions from adjacent frames exponentially decrease as separation between frames increases. Thus, the present efficient NST approach includes the use of an exponential moving average (EMA) temporal smoothing algorithm, which includes averaging accumulated contributions by:

$${\hat{v}}_{t}^{*} = \{ \begin{matrix}{\hat{v}}_{0} , & t = 0 \\ ( 1 - α ) {\hat{v}}_{t} + α T ( {\hat{v}}_{( t - 1 )}^{*} , {u}_{t - 1} ) , & t > 0\end{matrix} \qquad ( Equation 4 )$$

where uₜ and \hat{v}ₜ are the simulation and stylization velocities at the frame t, \hat{v}* is the velocity after EMA smoothing, and a is a weight that determines how temporally smooth the stylization will be. As noted above, the EMA temporal smoothing algorithm is used to average contributions from different image frames and works with contributions that are applied to the whole volume of the fluid simulation. The transport operator T aligns the stylization velocities (vₜ₋₁) from a previous image frame by transporting them with the underlying simulation velocity (uₜ₋₁). Then this aligned contribution from the previous image frame is merged with the current one by a combination of a weights, which may be selected by a user based on the user's preference.

FIG. 3 shows diagram 300 illustrating the effects of using different exemplary EMA α weights during the stylization process. As shown in FIG. 3, stylization 350a based on style sample 352 is produced using EMA α weight=0, stylization 350b based on the same style sample 352 is produced using EMA α weight=0.1, and stylization 350c based on the same style sample 352 is produced using EMA α weight=0.5. It is noted that, although not readily evident from the images shown in FIG. 3, while lower valued EMA α weights yield sharper results, the resulting patterns flicker through time.

A significant advantage of the use of EMA based smoothing in the present efficient NST approach is that since it accumulates contributions from multiple frames, it requires only one advection step to enforce temporal smoothness of per-frame iterations. Thus, EMA smoothing enables the direct use of the TNST approach without having to convert the grid into particles, while advantageously maintaining temporal coherency and computational efficiency. It is emphasized that the efficient NST approach disclosed by the present application is advantageously faster than conventional approaches due the use of EMA smoothing. This improvement enables the performance of stylization without converting the data to particles as is required in conventional LNST, and makes the present approach suitable for use on a large scale for production.

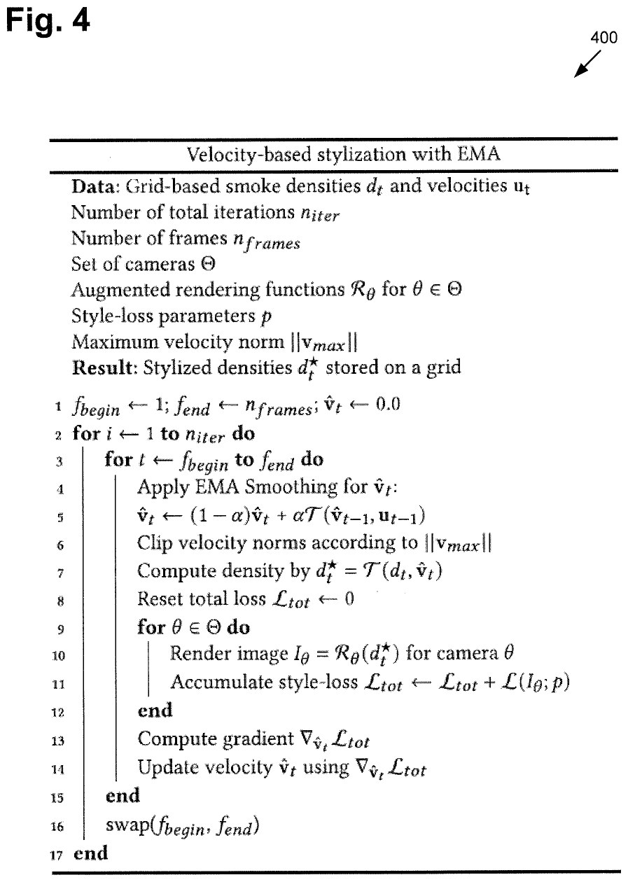

One particular distinction of EMA is that each iteration of the stylization can cycle through the entire frame range of the input simulation. By swapping the time direction during the cycle, temporal coherency is implemented holistically, producing patterns that will be affected both by the previous and next frames relative to that pattern. FIG. 4 shows pseudocode 400 and exemplary algorithm for coupling EMA smoothing with velocity-based stylization, according to one implementation.

Lagrangian neural style transfer has two modes: 1) optimizing for densities carried by the particles (ρ°), or 2) optimizing for the particle positions (x°). The majority of the results presented by the conventional LNST method used per-particle density attributes, which are easier to tune, converged faster and had higher quality for high-frequency styles. Naively implementing the same approach in a grid-based framework will produce undesirable artifacts such as time-incoherent sinks and sources which may hinder the convergence of the optimization, especially with simulations that change significantly over time.

The efficient NST approach disclosed by the present application introduces an adaptation to TNST that only allows changes by modulating the input density with a scaling factor s:

ŝ=argmin sΣ_{θ∈Θ}L(R_{θ}(d·s),p), s.t.ŝ(x)∈[sₘᵢₙ,sₘₐₓ] (Equation 5)

where [sₘᵢₙ, sₘₐₓ] is a bounded interval that constrains the minimum and maximum values of the density modulation in a certain grid voxel. Thus, the stylizing performed according to the present efficient NST approach limits modulations to the input density of image content included in each of first sequence of images 124, in FIG. 1A, to multiplication by a scaling factor.

The approach presented in Equation 5 above is especially useful for view-independent stylizations (discussed below), or when using images that have fine-detail structures. The changes needed in the algorithm described by pseudocode 400 to model the density-based stylization are minimal: the stylization velocity \hat{v}ₜ is replaced by a density modulation field ŝₜ, the transport T(dₜ, \hat{v}ₜ) is replaced by dₜ·ŝₜ and scale factors ŝₜ are clamped to the interval [sₘᵢₙ, sₘₐₓ].

It is noted that implementing hard-limiters for changes during the optimization are also useful for the velocity-based version of TNST (Equation 1). In this case, however, velocity magnitudes are constrained to be inside a parameter ∥\hat{v}(x)∥<\hat{v}ₘₐₓ. In Kim et al. [2019], the authors used an expanded and blurred density mask that modulates velocities in order to prevent the smoke from “leaking-out” from its original shape. While effective, this choice creates temporal coherency issues across the border of the smoke, due the smoke changing abruptly in its boundary regions. The velocity magnitude limiter is a more intuitive control, since artists can directly control the amount of stylization and also how much the stylization will expand the original simulation with a single parameter.

Referring to FIGS. 1A and 2 in combination, the features of the present efficient NST approach described above result in stylized content 132 including view-dependent second sequence of images 134, i.e., content 130 depicted by first sequence of images 124 having the desired stylization described by style data 126. Nevertheless, in some implementations, production of view-dependent stylized content 1 may be satisfactory, and in such use cases the method outlined by flowchart 240 further includes outputting, by software code 110 executed by hardware processor 104 of system 100, stylized content 132 as view-dependent stylized content including view-dependent second sequence of images 134 having the desired stylization (action 243).

However, in implementations in which system 100 includes ML model 114, stylizing content 130 may further include transforming view-dependent second sequence of images 134, using ML model 114, to view-independent sequence of images 136 (optional action 242b). When included in method outlined by flowchart 240, optional action 242b may be performed by software code 110, executed by hardware processor 104 of system 100, and using ML model 114, as described below In implementations in which optional action 242b is performed, subsequent action 243 includes outputting, by software code 110 executed by hardware processor 104 of system 100, stylized content 132 as view-independent stylized content including view-independent sequence of images 136 having the desired stylization.

As noted above by reference to action 241, first sequence of images 124 may include a plurality of 2D images depicting content 130. Nevertheless, stylized content 132 output in action 243 is three-dimensional (3D), regardless of whether stylized content includes view-dependent second sequence of images or view-independent sequence of images 136. It is noted that the content being stylized according to the present novel and inventive concepts is a time varying volumetric simulation that gets rendered into a set of images. A 2D stylization image is fed into the pipeline as input. The gradients are back propagated from the 2D image to the 3D volume by the use of a differentiable renderer.

It is further noted that the efficiency of the novel and inventive approach to content stylization disclosed by the present application is such that when first sequence of images 124 includes up to one hundred and sixty images, such as one hundred and twenty frames of video for example, system 100 may be capable of outputting stylized content 132 including view-dependent second sequence of images 134 or view-independent sequence of images 136 in less than three minutes from receiving first sequence of images 124. The process of transforming view-dependent stylized content to view-independent stylized content is described below.

The volumetric stylization described above to produce view-dependent stylized content 132 is heavily dependent on the camera configuration: i.e., the content matches the style for a set of specified cameras. While this approach allows screen-space control when using a single perspective camera, it fails to stylize for views that were unavailable to the optimizer. To minimize view-dependent artifacts, the stylization can use a larger set of cameras per-frame to be sampled around either a pre-specified path or on a surface of a sphere enclosing the object. When the camera is sampled on a sphere enclosing the object, a uniform sampling on the sphere is typically performed and then positions may be optimized to follow a Poisson-disk distribution. However, this process causes stylization to be inefficient, requiring up to several minutes per frame.

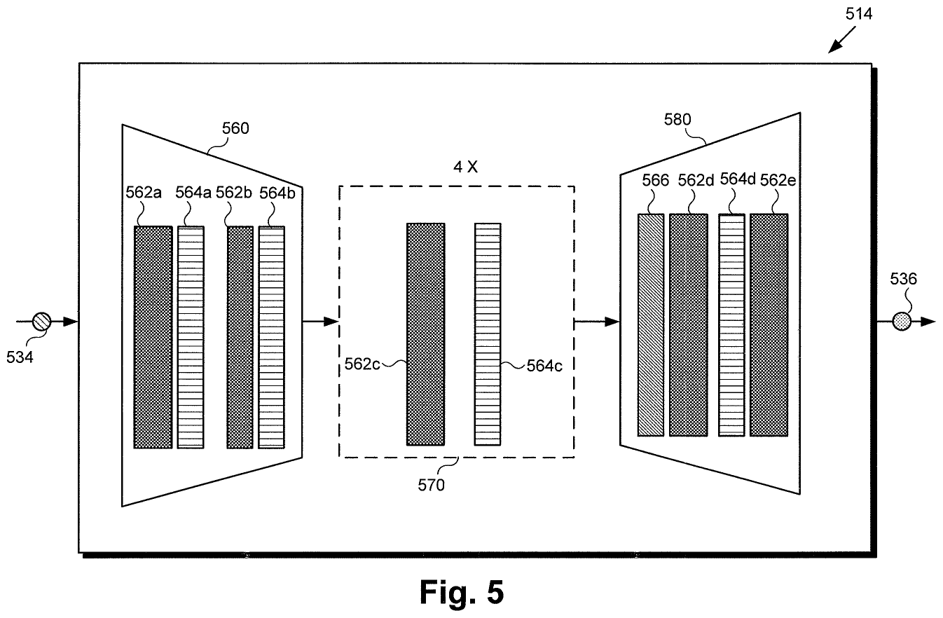

To avoid the inefficiency described above, the present efficient NST approach implements ML model 114 as an exemplary feed-forward 3D CNN that takes volumetric density as input and outputs a stylized version of that input. FIG. 5 shows a diagram of an exemplary feed-forward CNN architecture suitable for use as ML model 514 trained to provide view-independent stylized content. As shown in FIG. 5, ML model 514 receives view-dependent second sequence of images 534 as an input, and transforms view-dependent second sequence of images 534 to view-independent sequence of images 536, which is provided as an output by ML model 514.

As further shown by FIG. 5, an encoder-decoder architecture is utilized to implement the feed-forward network of ML model 514. Encoder 560 includes two strided convolutions each followed by a LeakyReLU activation function with a negative slope of 0.01:5×5×5 convolution 562a followed by LeakyReLU activation function 564a, and 3×3×3 convolution 562b followed by LeakyReLU activation function 564b, to decrease the spatial resolution by a factor of 4. Once the original density is downsampled four 3×3×3 convolutions 562c with stride 1 each followed by LeakyReLU activation function 564c are applied in block 570. Decoder 580 first applies two upsampling steps: trilinear upsampling 566 and 3×3×3 convolution 562d, followed by LeakyReLU activation function 564d, which is followed by final 3×3×3 convolution 562e reducing the number of channels.

It is noted that ML model 514, view-dependent second sequence of images 534, and view-independent sequence of images 536 correspond respectively in general to ML model 114, view-dependent second sequence of images 134, and view-independent sequence of images 136, in FIG. 1A. Consequently, ML model 114, view-dependent second sequence of images 134, and view-independent sequence of images 136 may share any of the characteristics attributed to respective ML model 514, view-dependent second sequence of images 534, and view-independent sequence of images 536 by the present disclosure, and vice versa. That is to say, although not shown in FIG. 1A, ML model 114 may include all of the features of ML model 514 described above.

ML model 114/514 trains to minimize either Equation 1 (velocity-based) or Equation 3 (density-based) in an unsupervised fashion, which avoids the need to generate input-output pairs to train the network in a supervised manner. By limiting training to a single stylization configuration (e.g., input image, size, etc.), the network can remain lightweight. The training procedure takes individual patches of the input training dataset, stylizing them independently. Since the network is convolutional in its implementation, it can be evaluated for a different resolution than originally trained for.

The feed-forward network ML model 114/514 generalizes and extends to distributions that were not in the training dataset. Moreover, temporal coherence is not explicitly enforced for the feed-forward network. Instead translational equivariance and continuity of the architecture output are relied upon to produce temporally coherent stylizations. It is contemplated that because the loss is trained on the style-space of the rendered volume, which, as noted above is an abstraction that can represent all possible stylizations of an image, that loss is better able to enforce filters that are transformation-invariant, generalizing well for sequences that were not seen during training time. That is to say, temporal coherency is almost automatically enforced by the structure of feed-forward network ML model 114/514, so that additional actions need not be performed for temporal coherency.

Thus, the present application discloses systems and methods for performing efficient NST for fluid simulations. As noted above, the efficient NST solution disclosed by the present application adapts volumetric style transfer methods (transport-based TNST and particle-based LNST) to production pipelines by making them more efficient and customizable while also reducing artifacts created by previous techniques. Moreover, and as also noted above, the present disclosure provides a simple architecture that is able to ensure that stylizations are consistent for arbitrary views, removing the view dependency of the screen-space style transfer. Thus, the present efficient NST solution advances the state-of-the-art by providing a simplified and more efficient mathematical optimization formulation in which costly advection algorithms are replaced by simpler mapping functions without loss of quality, by providing an improved temporal smoothing algorithm that improves the transport-based algorithm running time by more than two orders of magnitude, by extending the original transport-based approach to work directly with density values through a multiplicative factor, and by disclosing an efficient feed-forward architecture that is able to stylize volumetric simulations from arbitrary viewpoints, i.e., produce view-independent stylizations.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described herein, but many rearrangements, modifications, and substitutions are possible without departing from the scope of the present disclosure.

What is claimed is:

1. A system comprising:
a hardware processor; and
a system memory storing a software code and a machine learning (ML) model trained to apply a stylization to an image;
the hardware processor configured to execute the software code to:
receive a first sequence of images and style data describing a desired stylization of content depicted by the first sequence of images;
stylize the content, using the ML model, to provide a stylized content having the desired stylization, wherein stylizing includes applying an exponential moving average (EMA) temporal smoothing algorithm to sequential image pairs of the first sequence of images to generate a second sequence of images providing a depiction of the content having the desired stylization; and
output the stylized content having the desired stylization.

2. The system of claim 1, wherein the first sequence of images comprise two-dimensional (2D) images, and wherein the stylized content is three-dimensional (3D).

3. The system of claim 1, wherein the ML model comprises a neural network.

4. The system of claim 1, wherein stylizing further comprises use of a transport function having a first-order Euler integrator.

5. The system of claim 1, wherein the first sequence of images comprises up to one hundred and sixty images, and wherein the stylized content is output in less than three minutes from receiving the first sequence of images.

6. The system of claim 1, wherein stylizing limits modulations to an input density of image content included in each of the first sequence of images to multiplication by a scaling factor.

7. The system of claim 1, wherein the hardware processor is further configured to execute the software code to:
transform the second sequence of images, using another ML model, to a view-independent sequence of images;
wherein the stylized content includes the view-independent sequence of images.

8. The system of claim 7, wherein the another ML model comprises a feed-forward convolutional neural network.

9. The system of claim 1, wherein the content comprises a simulation of at least one of a fluid or a suspension of airborne particulates, in motion.

10. The system of claim 9, wherein the at least one of the fluid or the suspension of airborne particulates comprises smoke.

11. A method for use by a system including a hardware processor and a system memory storing a software code and a machine learning (ML) model trained to apply a stylization to an image, the method comprising:
receiving, by the software code executed by the hardware processor, a first sequence of images and a style data describing a desired stylization of content depicted by the first sequence of images;
stylizing the content, by the software code executed by the hardware processor and using the ML model, to provide a stylized content having the desired stylization, wherein stylizing includes applying an exponential moving average (EMA) temporal smoothing algorithm to sequential image pairs of the first sequence of images to generate a second sequence of images providing a depiction of the content having the desired stylization; and
outputting, by the software code executed by the hardware processor, the stylized content having the desired stylization.

12. The method of claim 11, wherein the first sequence of images comprise two-dimensional (2D) images, and wherein the stylized content is three-dimensional (3D).

13. The method of claim 11, wherein the ML model comprises a neural network.

14. The method of claim 11, wherein stylizing further utilizes a transport function having a first-order Euler integrator.

15. The method of claim 11, wherein the first sequence of images comprises up to one hundred and sixty images, and wherein the stylized content is output in less than three minutes from receiving the first sequence of images.

16. The method of claim 11, wherein stylizing limits modulations to an input density of image content included in each of the first sequence of images to multiplication by a scaling factor.

17. The method of claim 11, further comprising:
transforming the second sequence of images, by the software code executed by the hardware processor and using another ML model, to a view-independent sequence of images;
wherein the stylized content includes the view-independent sequence of images.

18. The method of claim 17, wherein the another ML model comprises a feed-forward convolutional neural network.

19. The method of claim 11, wherein the content comprises a simulation of at least one of a fluid or a suspension of airborne particulates, in motion.

20. The method of claim 19, wherein the at least one of the fluid or the suspension of airborne particulates comprises smoke.
